(19) United States
(12) Patent Application Publication
(10) Pub. No.: US 2015/0283469 A1
(43) Pub. Date: Oct. 8, 2015

(54) WIRELESS COMMUNICATION DEVICE SUPPORT STRUCTURE

(71) Applicant: Natasha L. Barnes, Austin, TX (US)

(72) Inventor: Natasha L. Barnes, Austin, TX (US)

(21) Appl. No.: 14/245,860

(22) Filed: Apr. 4, 2014

(51) Int. Cl. A63H 3/00; H05K 5/00; A63H 3/02; H05K 5/02

(52) U.S. Cl. CPC A63H 3/003; H05K 5/02; H05K 5/0086; A63H 3/02

(57) ABSTRACT

A wireless communication device support structure includes a stuffed animal having a plurality of sets of device holding members on a first one of opposing sides of the main body. Each one of the device holding members defines a pocket for receiving a respective corner of a wireless communication device. The device holding members of a first one of the sets of device holding members are arranged for having corners of a communication device of a first size received therein. The device holding members of a second one of the sets of device holding members are arranged for having corners of a communication device of a second size different than the first size received therein.

### FIELD OF THE DISCLOSURE

The disclosures made herein relate generally to accessories for wireless communication devices and, more particularly, to a plush toy (e.g., a stuffed animal) configured for holding a wireless communication device such as a smartphone or tablet in a use orientation.

### BACKGROUND

Wireless communication devices such as, for example, smartphones and tablets have become commonplace. Wireless communication devices are used for any number of purposes. In many instances, a wireless communication device is used for providing entertainment and educational purposes to a child. In such instances, it can be useful and desirable for the wireless communication device to be held in a use orientation (e.g., upright) using an article that the child has familiarity with and/or finds comfort with. To this end, a plush toy such as that in the form of a stuffed animal, which is configured for holding a wireless communication device in an orientation enabling its use, would be beneficial, desirable and useful.

### SUMMARY OF THE DISCLOSURE

Embodiments of the present invention are directed to a plush toy configured for holding a wireless communication device in an orientation enabling its use. Preferably, the stuffed toy is self-supporting (e.g., in a natural position of an animal depicted by the plush toy) and the wireless communication device is in a use orientation (e.g., screen thereof in an upright orientation) when the plush toy is in such natural position. To accommodate different configurations of wireless communication devices, embodiments of the present invention have a plurality of sets of device holding structures that are spaced apart in a manner whereby different sets of device holding structures are used for holding wireless communication devices of different sizes. For example, a first set of device holding structures can be provided for holding a tablet and a second set of device holding structures (e.g., smaller and closer together than the first set of device holding structures) can be provided for holding a smartphone.

In one embodiment of the present invention, a wireless communication device support structure comprises a stuffed animal having a plurality of sets of device holding members on a first one of opposing sides of the main body. Each one of the device holding members defines a pocket for receiving a respective corner of a wireless communication device. The device holding members of a first one of the sets of device holding members are arranged for having corners of a communication device of a first size received therein. The device holding members of a second one of the sets of device holding members are arranged for having corners of a communication device of a second size different than the first size received therein.

In another embodiment of the present invention, a wireless communication device support structure comprises a plush toy and a first set of device holding members. The plush toy has a main body and plurality of appendages extending from the main body. The first set of device holding members includes one or more upper device holding members and two lower device holding members. The one or more upper device holding members of the first set is attached to the main body of the plush toy. A first one of lower device holding members of the first set is attached to a first one of the appendages. A second one of lower device holding members of the first set is attached to a second one of the appendages.

These and other objects, embodiments, advantages and/or distinctions of the present invention will become readily apparent upon further review of the following specification, associated drawings and appended claims.

### BRIEF DESCRIPTION OF THE DRAWINGS

FIG. 1 is a side view showing a wireless communication device support structure configured in accordance with an embodiment of the present invention.

FIG. 2 is a side view of the wireless communication device support structure shown in FIG. 1 with a prior art wireless communication device mounted thereon.

FIG. 3 is a side view of the wireless communication device support structure shown in FIG. 1.

FIG. 4 is a top view of the wireless communication device support structure shown in FIG. 1.

### DETAILED DESCRIPTION

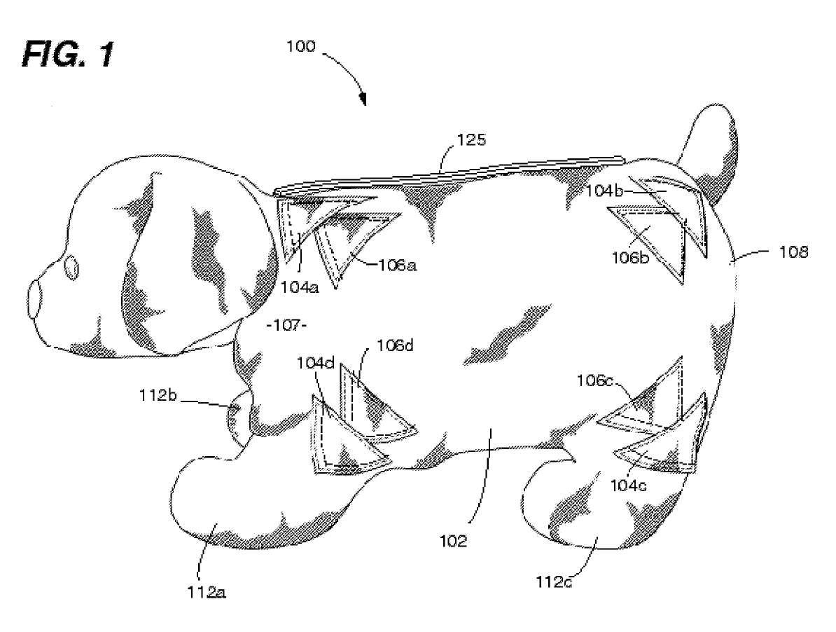

FIGS. 1-3 show various aspects of a wireless communication device support structure 100 configured in accordance with an embodiment of the present invention. The wireless communication device support structure 100 includes a stuffed animal 102 (i.e., a plush toy) having a set of first device holding members 104a-104d and a set of second device holding members 106a-106d. The set of first device holding members 106a-106d and the set of second device holding members 106a-106d are each attached to a first side 107 of a main body 108 of the stuffed animal 102. The first and second device holding members 104a-104d, 106a-106d can be attached to the main body 108 by any suitable means such as, for example, stitching, adhesive, thermal bonding, and the like.

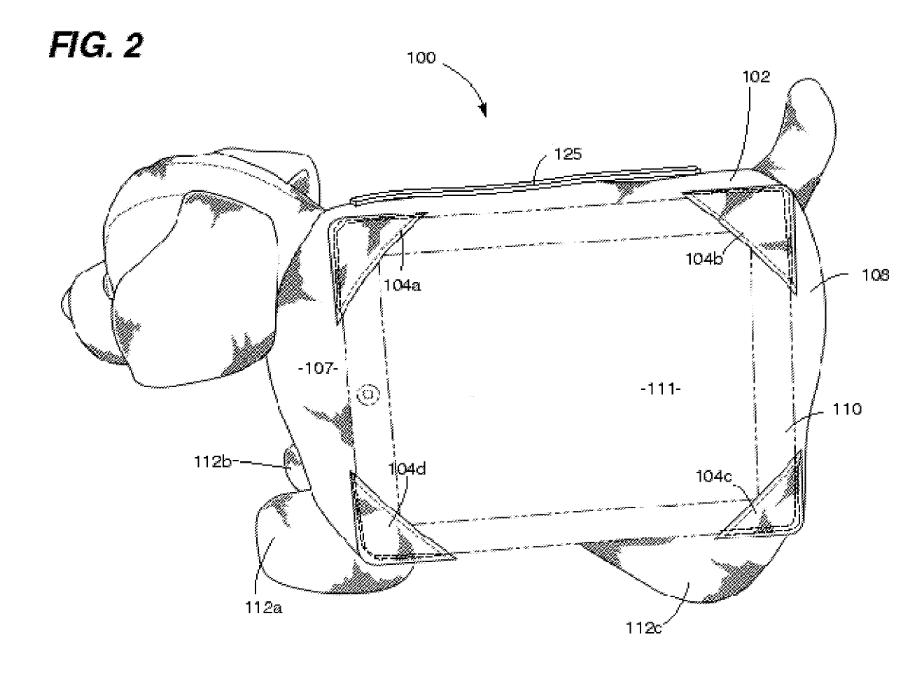

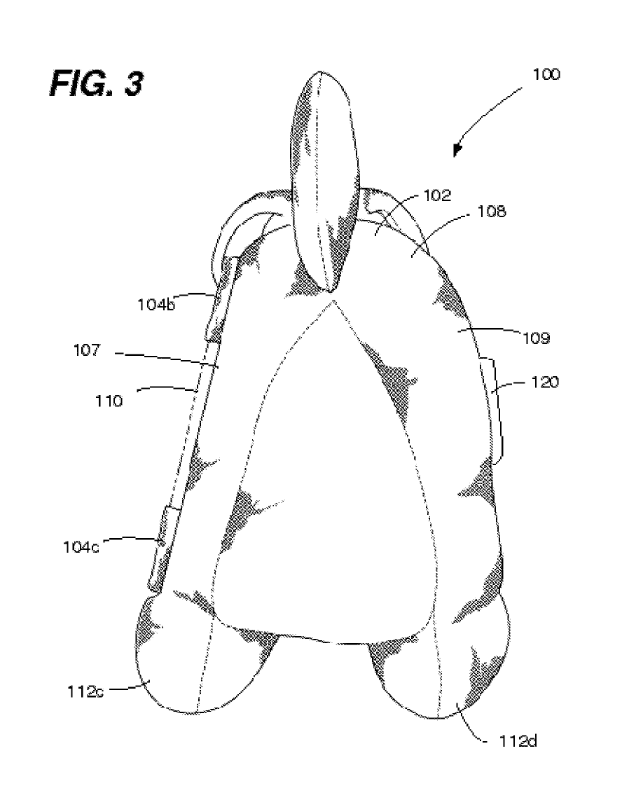

Each one of the first and second device holding members 104a-104d, 106a-106d defines a pocket (or slit, eyelet, or the like) for receiving a respective corner of a wireless communication device 110 (e.g., the tablet shown in FIGS. 2 and 3). In this regard, the first set of device holding members 104a-104d are arranged for having corners of a communication device of a first size received therein. Similarly, second set of device holding members 106a-106d are arranged for having corners of a communication device of a second size different than the first size received therein. As shown in FIG. 1, the first device holding members 104a-104d are arranged to define a first rectangle having a first width and a first height and the second device holding members 106a-106d are arranged to define a second rectangle having a second width less than the first width and a second height less than the first height. Preferably, as shown in FIG. 1, but not necessarily, the rectangle defined by the second device holding members 106a-106d is centered within the rectangle defined by the first device holding members 104a-104d.

It is disclosed herein that, in one specific alternate embodiment of the present invention, the set of first device holding members 104a-104d and the set of second device holding members 106a-106d are non-centered and share one common device holding member. For example, the first device holding member 104a could be a shared device holding member such that a set of first device holding members and a set of second device holding members in this alternate embodiment each include three (3) non-shared device holding members. In this regard, two adjacent edges of each rectangle defined by such sets of first and second device holding members would be aligned (i.e., overlaying each other).

For clarity, it is disclosed herein that the double-dashed lines at the perimeter edges of the first and second device holding members 104a-104d, 106a-106d represent stitching that attaches a respective one of the first and second device holding members 104a-104d, 106a-106d to the main body 108 and the single-dashed lines at the perimeter edges of the first and second device holding members 104a-104d, 106a-106d represent stitching for providing a hem. As such, an entry into a corner receiving space (i.e., cavity) defined between a particular one of the first and second device holding members 104a-104d, 106a-106d each one of the first and second device holding members 104a-104d, 106a-106d is provided along the edge portion having the stitching for providing a hem (i.e., not having the stitching that attaches a respective one of the device holding members to the main body). It is disclosed herein that all or a portion of the device holding members can have a shape other than triangular (e.g., an elongated strap of material).

It is disclosed herein that, in other embodiments of the present invention, the first device holding members 104a-104d can be attached to one side of the main body 108 of the stuffed animal 102 and the second device holding members 106a-106d can be attached to a different side of the main body 108 of the stuffed animal 102. For example, the first device holding members 104a-104d can be attached to the first side 107 of the main body 108 and the second device holding members 106a-106d can be attached to a second side 109 of the main body 108. Advantageously, such a construction will allow two different wireless communication devices to be simultaneously supported by the stuffed animal 102 in a manner allowing simultaneous use (i.e., viewing of visual displays thereof).

As shown in FIGS. 1-3, the set of first device holding members 104a-104d includes two spaced apart upper device holding members 104a-104b and two spaced apart lower device holding members 104c-104d and the set of second device holding members 106a-106d includes two spaced apart upper device holding members 106a-106b and two spaced apart lower device holding members 106c-106d. As also shown in FIGS. 1-3, the corner receiving space of each one of the first device holding members 104a-104d has a maximum depth that is greater than the corner receiving space of each one of the second device holding members 106a-106d (i.e., as measured from the edge at the hem stitching). This differential size is advantageous so that an area of a visual display covered by the second device holding members 106a-106d is less than that covered by the first device holding members 104a-104d. This can be beneficial because an area of a visual display of a wireless communication device engaged with the second device holding members 106a-106d will generally be smaller than an area of a visual display of a wireless communication device engaged with the first device holding members 104a-104d. It is disclosed herein that, in other embodiments, the corner receiving space of each one of the first device holding members 104a-104d can be substantially the same as the corner receiving space of each one of the second device holding members 106.

In view of the disclosures made herein, a skilled person will appreciate that the first and second device holding members 104a-104d, 106a-106d can have a variety of configurations. In one alternate embodiment, a single elongated device holding member can replace the two upper device holding members of either set and/or a single elongated device holding member can replace the two lower device holding members of either set. In another alternate embodiment, one or both of the sets of the device holding members can be replaced with a single left device holding member and a single right device holding member of a single upper device holding member and a single lower device holding member. Such alternate device holding members would be elongated for being engaged with a respective upper and lower edge portions or left and right edge portions of a wireless communication device.

A plurality of legs 112a-112d are attached to the main body 108 of the stuffed animal 102. The legs 112a-112d are examples of appendages. Arms are another example of such appendages. Front leg 112a and rear leg 112c are located at the first side 107 of the main body 108 and front leg 112c and rear leg 112d) are located at the second side 109 of the main body 108. The legs 112a-112d are jointly configured (e.g., of suitable size and density) for being engaged with a support surface (e.g., table, floor or the like) for causing the first and second sides 107, 109 of the main body 108 to be generally upright with respect to the support surface when the legs 112a-112d are engaged with the support surface. In this regard, the device holding members 104a-104d, 106a-106d, which are attached to a side of the main body 108 are in a position for allowing the visual display 111 of the wireless communication device 110 to be visually and/or physically accessed while the legs 112a-112d are engaged with the support surface. Preferably, but not necessarily, the first device holding members that are in the lower position (i.e., first device holding members 106c and 106d) are attached to an adjacent one of the legs (i.e., front leg 112a and rear leg 112c). Accordingly and advantageously, attachment of the first device holding members that are in the lower position to the adjacent legs results in the wireless communication device 108 spanning across an interface between the adjacent legs (i.e., front leg 112a and rear leg 112c), which adds rigidity to aid in maintaining the first and second sides 107, 109 of the main body 108 generally upright with respect to the support surface when the legs 112a-112d are engaged with the support surface. It is disclosed herein that the second device holding members that are in the lower position (i.e., second device holding members 104c and 104d) can be attached to an adjacent one of the legs (i.e., front leg 112a and rear leg 112c).

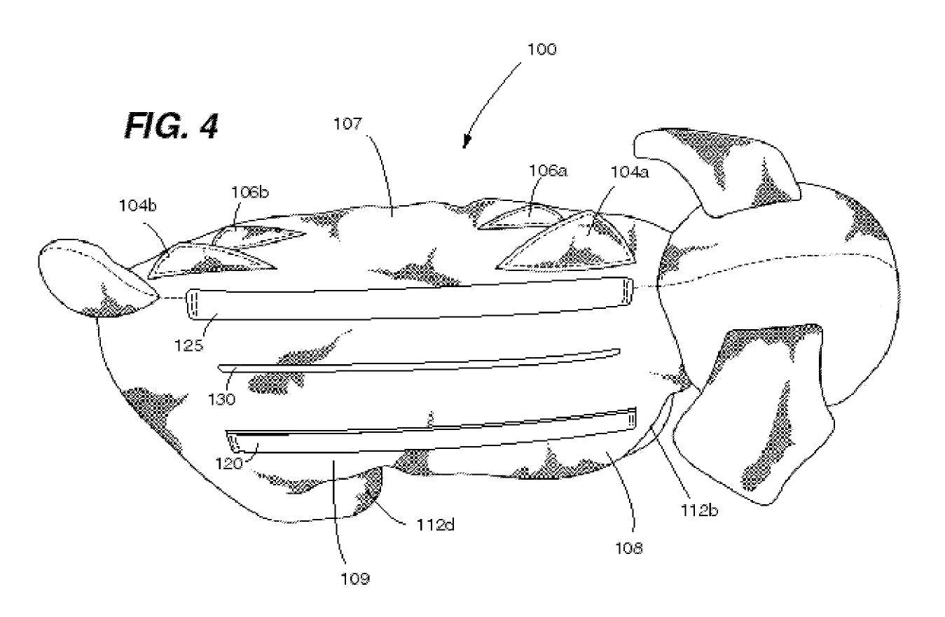

Referring to FIGS. 3 and 4, the wireless communication device support structure 100 can include a retention strap 120 that is attached to the main body 108. As shown, the retention strap 120 that is attached to the second side 109 of the main body 108. However, it is disclosed herein that the retention strap 120 can be attached to different location/portion of the main body 108. The retentions strap 120 can be engaged around an object such as, for example, a headrest of a vehicle for securing the wireless communication device support structure 100 to the object in a manner allowing the visual display 111 of the wireless communication device 110 to be accessed (e.g., viewed). To this end, the retention strap 120 can have a variable length (e.g., having elasticity, being of an adjustable, buckle/clasp and/or the like). A carrying strap 125 can be provided on the main body 108 for being used to carry the wireless communication device support structure 100.

Referring to FIG. 4, a pocket 130 (i.e., a cavity) can be provided in the main body 108 of the wireless communication device support structure 100. The pocket 130 serves as a storage space in which one or more wireless communications devices, accessories, etc can be stored. A flap, zipper, elastic beading, or other closure structure (not specifically shown) can be provided for covering and/or closing an access opening of the pocket 130. In preferred embodiments, the pocket 130 is provided within the second side 109 of the main body 108.

Although depicted herein as an animal, embodiments of the present invention are not limited to plush toy in the form of animals. For example, a plush toy configured in accordance with an embodiment of the present invention can be in the form of a vehicle (e.g., a car or truck with wheels/tires), a spacecraft with wings, a building structure, etc. Similarly, a plush toy configured in accordance with an embodiment of the present invention can be in the form of other living beings that are not animals (e.g., people, insects and the like). Still further, a plush toy configured in accordance with an embodiment of the present invention can be in the form of an entity such as a cartoon character, alien being, etc.

Although the invention has been described with reference to several exemplary embodiments, it is understood that the words that have been used are words of description and illustration, rather than words of limitation. Changes may be made within the purview of the appended claims, as presently stated and as amended, without departing from the scope and spirit of the invention in all its aspects. Although the invention has been described with reference to particular means, materials and embodiments, the invention is not intended to be limited to the particulars disclosed; rather, the invention extends to all functionally equivalent technologies, structures, methods and uses such as are within the scope of the appended claims.

What is claimed is:

1. A wireless communication device support structure, comprising:
a stuffed animal having a main body with opposing sides; and
a plurality of sets of device holding members attached to the stuffed animal on a first one of the opposing sides thereof, wherein each one of the device holding members defines a pocket for receiving a respective corner of a wireless communication device, wherein the device holding members of a first one of the sets of device holding members are arranged for having corners of a communication device of a first size received therein and wherein the device holding members of a second one of the sets of device holding members are arranged for having corners of a communication device of a second size different than the first size received therein.

2. The wireless communication device support structure of claim 1 wherein:
the device holding members of the first one of the sets of device holding members are arranged to define a first rectangle having a first width and a first height; and
the device holding members of the second one of the sets of device holding members are arranged to define a second rectangle having a second width less than the first width and a second height less than the first height.

3. The wireless communication device support structure of claim 2 wherein the second rectangle is centered within the first rectangle.

4. The wireless communication device support structure of claim 1 wherein:
each one of the sets of device holding members includes two spaced apart upper device holding members and two spaced apart lower device holding members; and
a corner receiving space of each one of the device holding members of the first one of the sets of device holding members has a maximum depth greater than a corner receiving space of each one of the device holding members of the second one of the sets of device holding members.

5. The wireless communication device support structure of claim 4 wherein:
the device holding members of the first one of the sets of device holding members are arranged to define a first rectangle having a first width and a first height; and
the device holding members of the second one of the sets of device holding members are arranged to define a second rectangle having a second width less than the first width and a second height less than the first height.

6. The wireless communication device support structure of claim 5 wherein the second rectangle is located within the first rectangle.

7. The wireless communication device support structure of claim 1 wherein:
the stuffed animal has a plurality of appendages attached thereto; and
the appendages are positioned on the main body and configured to be engaged with a support surface for causing the first one of the opposing sides of the main body to be generally upright with respect to the support surface when the appendages are engaged with the support surface.

8. The wireless communication device support structure of claim 7 wherein each one of the sets of device holding members includes two spaced apart upper device holding members and two spaced apart lower device holding members.

9. The wireless communication device support structure of claim 7 wherein:
each one of the sets of device holding members includes two spaced apart upper device holding members and two spaced apart lower device holding members;
the device holding members of the first one of the sets of device holding members are arranged to define a first rectangle having a first width and a first height; and
the device holding members of the second one of the sets of device holding members are arranged to define a second rectangle having a second width less than the first width and a second height less than the first height.

10. The wireless communication device support structure of claim 9 wherein the second rectangle is centered within the first rectangle.

11. The wireless communication device support structure of claim 7 wherein:
the main body has a storage space therein; and
an access opening into the storage space is within a side of the main body opposite a side of the main body to which the first and second sets of device holding members are attached.

12. The wireless communication device support structure of claim 11 wherein the main body has a retention strap attached to the side of the main body having the access opening in to the storage space.

13. The wireless communication device support structure of claim 12 wherein:
each one of the sets of device holding members includes two spaced apart upper device holding members and two spaced apart lower device holding members;
the device holding members of the first one of the sets of device holding members are arranged to define a first rectangle having a first width and a first height;
the device holding members of the second one of the sets of device holding members are arranged to define a second rectangle having a second width less than the first width and a second height less than the first height; and
the second rectangle is centered within the first rectangle.

14. A wireless communication device support structure, comprising:
a plush toy having a main body and plurality of appendages extending from the main body; and
a first set of device holding members including one or more upper device holding members and two lower device holding members, wherein the one or more upper device holding members of the first set is attached to the main body of the plush toy, wherein a first one of lower device holding members of the first set is attached to a first one of the appendages and wherein a second one of lower device holding members of the first set is attached to a second one of the appendages.

15. The wireless communication device support structure of claim 14 wherein the appendages are positioned on the main body and configured to be engaged with a support surface for causing a portion of the main body to which the first set of device holding members are attached to be generally upright with respect to the support surface when the appendages are engaged with the support surface.

16. The wireless communication device support structure of claim 14 wherein:
the first set of device holding members includes two upper device holding members that are each attached to the main body of the plush toy; and
the device holding members of the first set are arranged to define a first rectangle having a first width and a first height.

17. The wireless communication device support structure of claim 16 wherein the appendages are positioned on the main body and configured to be engaged with a support surface for causing a portion of the main body to which the first set of device holding members are attached to be generally upright with respect to the support surface when the appendages are engaged with the support surface.

18. The wireless communication device support structure of claim 14, further comprising:
a second set of device holding members including two upper device holding members and two lower device holding members;
wherein a size of each one of the device holding members of the first one of the sets of device holding members is substantially greater than a size of each one of the device holding members of the second one of the sets of device holding members;
wherein the upper and lower device holding members of the second set are attached to the main body of the plush toy;
wherein the upper and lower device holding members of the second set are arranged to define a second rectangle having a second width less than the first width and a second height less than the first height; and
wherein the second rectangle is located within the first rectangle.

19. The wireless communication device support structure of claim 18 wherein the appendages are positioned on the main body and configured to be engaged with a support surface for causing a portion of the main body to which the first set of device holding members are attached to be generally upright with respect to the support surface when the appendages are engaged with the support surface.

20. The wireless communication device support structure of claim 19 wherein:
the main body has a storage space therein;
an access opening into the storage space is within a side of the main body opposite a side of the main body to which the first and second sets of device holding members are attached; and
the main body has a retention strap attached to the side of the main body having the access opening in to the storage space.
